(19) United States
(12) Patent Application Publication
(10) Pub. No.: US 2024/0371660 A1
(43) Pub. Date: Nov. 7, 2024

(54) GAS SUPPLYING APPARATUS, GAS SUPPLY CONTROL METHOD, AND SUBSTRATE PROCESSING APPARATUS

(71) Applicant: SEMES CO., LTD., Cheonan-si (KR)

(72) Inventors: Hak Gyun HONG, Cheonan-si (KR); Jong Seok LEE, Cheonan-si (KR); Gi Jae YOON, Cheonan-si (KR); Myoung Hee JO, Cheonan-si (KR)

(73) Assignee: SEMES CO., LTD., Cheonan-si (KR)

(21) Appl. No.: 18/651,874

(22) Filed: May 1, 2024

(30) Foreign Application Priority Data
May 2, 2023 (KR) 10-2023-0057009

(51) Int. Cl. H01L 21/67

(52) U.S. Cl. CPC H01L 21/67017

(57) ABSTRACT

Proposed are a gas supplying apparatus, a gas supply control method, and a substrate processing apparatus. The device that supplies a gas to a chamber adapted to perform a processing operation on a substrate includes a gas supply line connected from a gas source to the chamber and providing a flow path for the gas, a circulation line branching off from a branch point of the gas supply line and connected to an upstream side of the branch point, an ejector having an internal space that sucks a gas provided from the circulation line using a pressure of the gas introduced from the gas source, and injecting the gas in the internal space into the gas supply line, and a flow control module configured to regulate a flow rate of the gas supplied to the chamber by controlling the pressure of the gas in the gas supply line.

### CROSS REFERENCE TO RELATED APPLICATION

The present application claims priority to Korean Patent Application No. 10-2023-0057009, filed May 2, 2023, the entire contents of which is incorporated by reference herein for all purposes.

### BACKGROUND OF THE INVENTION

### Field of the Invention

The present disclosure relates to a gas supplying apparatus that supplies gas to a chamber adapted to perform a processing operation on a substrate, a gas supply control method performed by the gas supplying apparatus, and a substrate processing apparatus including the gas supplying apparatus.

### Description of the Related Art

Semiconductor manufacturing is a process of manufacturing semiconductor devices on a substrate (e.g., wafer), and includes, for example, exposure, deposition, etching, ion implantation, cleaning, etc. In order to perform each manufacturing process, semiconductor manufacturing equipment for performing individual processes is provided in cleanrooms of a semiconductor manufacturing plant so that a process is performed on a substrate put into the semiconductor manufacturing equipment.

In the semiconductor manufacturing, various gases are used for processing substrates. Gas can be used for a variety of purposes depending on a process. For example, in the plasma etching process, a process gas to react with specific materials on a substrate may be supplied to a plasma processing chamber. A process gas used in the etching process may vary, and the flow rate of a supplied process gas may also vary depending on type or time.

In the process of changing the gas supply amount, a sudden error (hunting) may occur in the gas supply flow rate due to the pressure of a gas remaining in a gas supply line. Such errors may affect process performance.

### SUMMARY OF THE INVENTION

Accordingly, the present disclosure has been made keeping in mind the above problems occurring in the related art, and an objective of the present disclosure is to provide a gas supplying apparatus that supplies gas with precision, a gas supply control method, and a substrate processing apparatus.

In order to accomplish the above objectives, according to an embodiment of the present disclosure, there is provided a gas supplying apparatus that supplies a gas to a chamber adapted to perform processing on a substrate, the device including: a gas supply line connected from a gas source to the chamber and providing a flow path for the gas; a circulation line branching off from a branch point of the gas supply line and connected to an upstream side of the branch point; an ejector having an internal space that sucks a gas provided from the circulation line using a pressure of the gas introduced from the gas source, and injecting the gas in the internal space into the gas supply line; and a flow control module configured to regulate a flow rate of the gas supplied to the chamber by controlling the pressure of the gas in the gas supply line. The openness between the gas supply line and the circulation line may be controlled based on an internal pressure of the gas supply line and a control pressure of the flow control module.

According to the embodiment of the present disclosure, the ejector may include: a body forming the internal space; an inlet nozzle provided to allow the gas provided from the gas source to flow in; a suction nozzle provided to allow the gas provided from the circulation line to be sucked in; and a diffuser nozzle for spraying the gas in the internal space into the gas supply line.

According to the embodiment of the present disclosure, the gas supplying apparatus may further include: a first supply valve provided between the ejector and the flow control module; a second supply valve provided between the flow control module and the chamber; a first circulation valve provided at a position adjacent to the flow control module in the circulation line; a second circulation valve provided at a position adjacent to the ejector in the circulation line; a first pressure gauge provided in a first section between the first supply valve and the flow control module in the gas supply line; and a circulation line pressure gauge provided between the first circulation valve and the second circulation valve in the circulation line.

According to the embodiment of the present disclosure, the flow control module may include: a control valve provided at a position adjacent to the first supply valve and controlling an opening rate of the gas supply line; an orifice provided at a position adjacent to the second supply valve; a second pressure gauge provided in a second section between the control valve and the orifice in the gas supply line; a third pressure gauge provided in a third section between the orifice and the second supply valve; and a controller configured to control the control valve to maintain a pressure of the second section in the gas supply line at a set control pressure.

According to the embodiment of the present disclosure, the second supply valve may be set to repeatedly open and be closed by a pulse signal at regular intervals, and the gas may be supplied to the chamber at a supply flow rate determined by means of the control valve during a time the second supply valve is open.

According to the embodiment of the present disclosure, at a first timing when the second supply valve is opened, the control valve may be controlled so that a first control pressure corresponding to a first gas supply flow rate is maintained in the second section, and at a second timing when the second supply valve is closed, if a pressure of the gas remaining in the second section is greater than a second control pressure corresponding to a second gas supply flow rate in a third timing, the first circulation valve may be controlled to open for a set period of time.

According to the embodiment of the present disclosure, if a difference between a pressure of the gas remaining in the second section and a pressure of the gas remaining in the circulation line is greater than a reference value, the second circulation valve may be controlled to open at a third timing when the second supply valve is opened.

According to the embodiment of the present disclosure, the gas supplying apparatus may further include: a dump line branched from the circulation line at a position between the first circulation valve and the second circulation valve, and connected to a discharge end; and a dump valve provided on the dump line.

According to the embodiment of the present disclosure, during a blocking time when the second supply valve is closed, an opening of the dump valve may be controlled based on internal pressures of the gas supply line, an internal pressure of the circulation line, and a control pressure for gas supply after the blocking time.

According to the embodiment of the present disclosure, at a first timing when the second supply valve is opened, the control valve may be controlled so that a first control pressure corresponding to a first gas supply flow rate is maintained in the second section, at a second timing when the second supply valve is closed, if a pressure of the gas remaining in the second section is greater than a second control pressure corresponding to a second gas supply flow rate in a third timing, the second circulation valve may be controlled to open for a set period of time, at a third timing when the second supply valve is opened, the control valve may be controlled so that the second control pressure is maintained in the second section, and at a fourth timing when the second supply valve is closed, if a pressure of the first section is greater than a first reference value, a pressure of the circulation line is greater than a second reference value, and a pressure of the second section is greater than a third control pressure corresponding to a third gas supply flow rate in a fifth timing, the dump valve may be controlled to open.

According to an embodiment of the present disclosure, there is provided a gas supply control method performed by a gas supplying apparatus that supplies a gas to a chamber adapted to perform processing on a substrate, the method including: determining a control pressure of the flow control module based on a supply flow rate of the gas; and supplying the gas to the chamber at a supply flow rate corresponding to the control pressure.

According to an embodiment of the present disclosure, there is provided a substrate processing apparatus including: a chamber in which processing on a substrate is performed; a gas supplying apparatus configured to supply a gas to the chamber; and a control device configured to control an operation of the gas supplying apparatus.

According to the present disclosure, by configuring a gas circulation line that branches off from a gas supply line and connects to an ejector, hunting caused by the internal pressure of the gas supply line can be prevented and the supply flow rate of gas can be precisely controlled.

### BRIEF DESCRIPTION OF THE DRAWINGS

The above and other objectives, features, and other advantages of the present disclosure will be more clearly understood from the following detailed description when taken in conjunction with the accompanying drawings, in which:

FIG. 1 schematically shows the structure of a substrate processing apparatus including a gas supplying apparatus according to the present disclosure;

FIG. 2 shows a gas supplying apparatus according to a comparative example of the present disclosure;

FIG. 3 shows a case where hunting occurs during the gas supply process according to a comparative example of the present disclosure;

FIG. 4 shows a gas supplying apparatus according to an embodiment of the present disclosure;

FIG. 5 shows the configuration of a flow control device according to an embodiment of the present disclosure;

FIG. 6 shows the structure of an ejector according to an embodiment of the present disclosure;

FIG. 7 is a timing diagram for gas flow rate control performed by a gas supplying apparatus according to an embodiment of the present disclosure;

FIG. 8 is a timing diagram for gas flow rate control performed by a gas supplying apparatus to which a dump line is applied according to an embodiment of the present disclosure; and

FIG. 9 is a flowchart showing a gas supply control method according to an embodiment of the present disclosure.

### DETAILED DESCRIPTION OF THE INVENTION

Hereinafter, with reference to the accompanying drawings, embodiments of the present disclosure will be described in detail so that those skilled in the art may easily carry out the present disclosure. The present disclosure may be embodied in many different forms and is not limited to the embodiments set forth herein.

In order to clearly describe the present disclosure, parts irrelevant to the description are omitted, and the same reference numerals are assigned to the same or similar components throughout the specification.

In addition, in various embodiments, components having the same configuration will be described only in representative embodiments by using the same reference numerals, and in other embodiments, only configurations different from the representative embodiments will be described.

Throughout the specification, when a part is said to be “connected (or coupled)” to another part, this includes not only the case of being “directly connected (or coupled)” but also “indirectly connected (or coupled)” with another member in between. In addition, when a part “includes”, “has”, or “comprises” a certain part, this means that other components may be further included without excluding other components unless otherwise stated.

Unless otherwise defined, all terms used herein, including technical or scientific terms, have the same meaning as commonly understood by a person skilled in the art. Terms such as those defined in the commonly used dictionaries should be construed as having meanings consistent with the meanings in the context of the related art and shall not be construed in ideal or excessively formal meanings unless expressly defined in this application.

Hereinafter, a gas supplying apparatus, a gas supply control method, and a substrate processing apparatus according to an embodiment of the present disclosure will be described. The gas supplying apparatus, the gas supply control method, and the substrate processing apparatus according to the embodiment of the present disclosure are intended to prevent sudden changes in flow rate (hunting) that occur during the supply process by variably controlling the flow rate of gas. By preventing hunting during the gas supply process, the intended flow rate of gas may be supplied consistently, thereby improving the precision of the process.

The present embodiments and the drawings accompanying this specification only clearly show some of the technical ideas included in the present disclosure, and it will be apparent that all modifications and specific embodiments that may be easily inferred by those skilled in the art within the scope of the technical idea included in the specification and drawings of the present disclosure are included in the scope of the present disclosure.

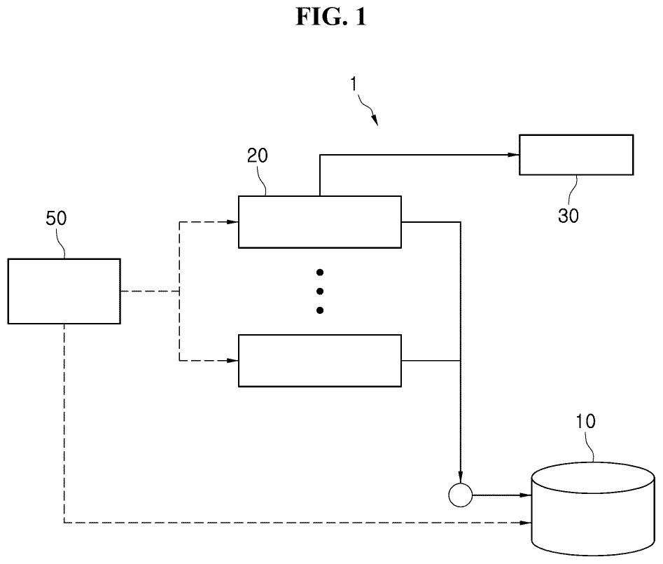

FIG. 1 schematically shows the structure of a substrate processing apparatus 1 including a gas supplying apparatus 20 according to the present disclosure. The substrate processing apparatus 1 performs processes on substrates (e.g., wafers, glass). The substrate processing apparatus 1 may perform a process (e.g., etching, deposition) on a substrate input through an interface unit and discharge the substrate to the outside for the next process.

The substrate processing apparatus 1 includes: a chamber 10 in which processing on a substrate is performed; the gas supplying apparatus 20 that supplies gas to the chamber 10; and a control device 50 that controls the operation of the gas supplying apparatus 20.

The chamber 10 provides space for performing processing on a substrate. The inside of the chamber 10 may be provided with a chuck on which the substrate is seated, a nozzle (or showerhead) for supplying gas to the internal space of the chamber 10, and an electrode for generating plasma in the internal space of the chamber 10. The gas supplying apparatus 20 may supply gas to the internal space of the chamber 10.

The gas supplying apparatus 20 may be connected to a gas supply pipe provided in the chamber 10. A plurality of gas supplying apparatus 20 may be provided. Each gas supplying apparatus 20 may supply a specific gas to the chamber 10. Each gas supplying apparatus 20 may supply gas at a set flow rate.

The control device 50 may control the operation of each component of the gas supplying apparatus 20. The control device 50 may store recipe data received from a higher-level control system or recipe data input in advance. The control device 50 may control the gas supplying apparatus 20 so that processing is performed according to the stored recipe data. In addition, the control device 50 may control the overall operation of the substrate processing apparatus 1, including other components of the substrate processing apparatus 1. The control device 50 may include a memory, a processor, a communication module, and an input/output interface. The gas supply control method described below may be performed by the control device 50. The processor of the control device 50 may generate a control signal for gas supply and transmit the control signal to the gas supplying apparatus 20.

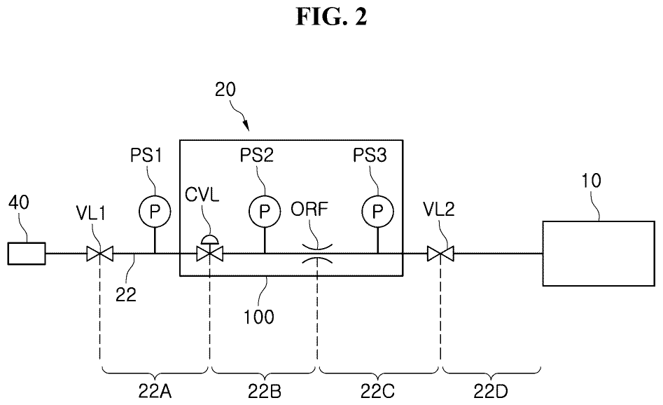

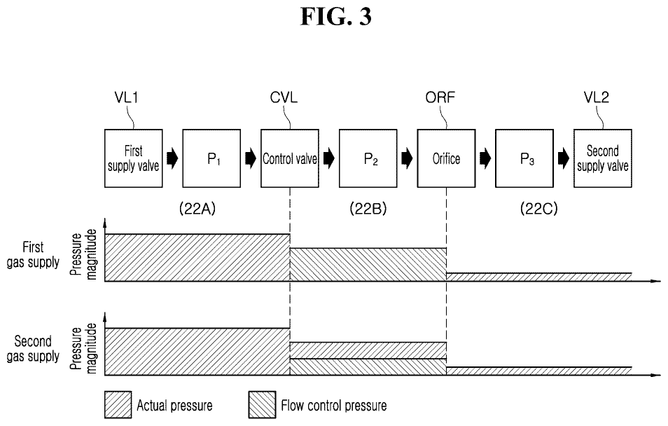

FIG. 2 shows a gas supplying apparatus 20 according to a comparative example of the present disclosure, and FIG. 3 shows a case where hunting occurs during the gas supply process according to a comparative example of the present disclosure.

Referring to FIG. 2, the gas supplying apparatus 20 includes: a gas supply line 22 connected to a gas source 40; a flow control module 100 for controlling the flow rate of gas in the gas supply line 22; and a first supply valve VL1 and a second supply valve VL2 respectively provided on the upstream and downstream sides of the flow control module 100; and a first pressure gauge PS1 that measures the pressure of gas between the first supply valve VL1 and the flow control module 100. The flow control module 100 includes: a control valve CVL and orifice ORF for regulating the supply pressure of gas; and a second pressure gauge PS2 and a third pressure gauge PS3 provided with the orifice ORF in between. The first pressure gauge PS1 measures a pressure P₁ of a gas flowing into the flow control module 100 in a first section 22A of the gas supply line 22, the second pressure gauge PS2 measures a pressure P₂ on the upstream side of the orifice ORF (a second section 22B of the gas supply line 22), and the third pressure gauge PS3 measures a pressure P₃ on the downstream side of the orifice ORF (a third section 22C of the gas supply line 22). Gas whose flow rate is controlled by the flow control module 100 is supplied to the chamber 10 through a fourth section 22D of the gas supply line 22.

The flow control module 100 is a pressure-based fluid control device. The flow control module 100 is a device that controls the flow rate of gas by regulating the pressure P₂ under the critical expansion condition, that is, the condition where the pressure P₂ on the upstream side of the orifice ORF is more than twice the pressure P₃ on the downstream side (i.e., P₂≥2P₃). Under the critical expansion condition, the velocity of a gas flowing through the orifice ORF is always maintained at the speed of sound, and thus the flow rate may only be proportional to the pressure P₂ on the upstream side. Therefore, the flow control module 100 may control the flow rate of a gas by regulating the pressure P₂ on the upstream side of the orifice ORF using the control valve CVL and the second pressure gauge PS2.

In the process of controlling the flow rate using pressure, a sudden error in the gas supply flow rate may occur due to the pressure of a gas remaining in the gas supply line 22. Referring to FIG. 3, when primarily supplying gas, gas under a certain level of supply pressure P₁ flows in the first section 22A by means of the first supply valve VL1. Gas under the pressure P₂ controlled by means of the control valve CVL flows through the second section 22B, and gas at a flow rate set by means of the orifice ORF flows through the third section 22C. In this case, when the pressure P₃ of the third section 22C is less than half of the pressure P₂ of the second section 22B, the gas flow rate of the third section 22C is determined in proportion to the pressure P₂ of the second section 22B.

During the first gas supply period, gas may flow in the second section 22B under a first pressure (e.g., 30 Torr). At this time, in the third section 22C, gas may be supplied at a first flow rate (150 cc/min). Thereafter, gas is supplied at a second flow rate (e.g., 100 cc/min) during the secondary gas supply period. At this time, the gas is controlled to a second pressure (e.g., 20 Torr) in the second section 22B. In this case, gas under the first pressure greater than the second pressure may remain in the second section 22B during the first gas supply period. When the second supply valve VL2 is opened while the gas under the first pressure remains in the second section 22B, gas at a flow rate that greatly deviates from a set flow rate may be instantly supplied to the chamber 10. That is, when supplying gas, hunting may occur due to hysteresis of the previous recipe.

Embodiments of the present disclosure are intended to provide a gas supplying apparatus, a gas supply control method, and a substrate processing apparatus, which may prevent hunting due to hysteresis of the previous recipe.

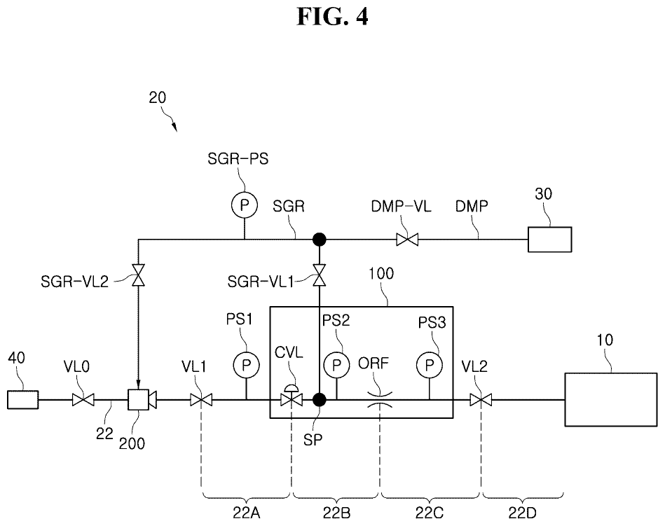

FIG. 4 shows a gas supplying apparatus 20 according to an embodiment of the present disclosure. The gas supplying apparatus 20 according to the present disclosure includes: a gas supply line 22 connected from a gas source 40 to a chamber 10 and providing a flow path for a gas; a circulation line SGR branching off from a branch point SP of the gas supply line 22 and connected to the upstream side of the branch point SP; an ejector 200 having an internal space IS that sucks a gas provided from the circulation line SGR using the pressure of a gas introduced from the gas source 40, and injecting the gas in the internal space IS into the gas supply line 22; and a flow control module 100 that controls the flow rate of a gas supplied to the chamber 10 by regulating the pressure of the gas in the gas supply line 22. In addition, the gas supplying apparatus 20 includes: a first supply valve VL1 provided between the ejector 200 and the flow control module 100; a second supply valve VL2 provided between the flow control module 100 and the chamber 10; a first circulation valve SGR-VL1 provided at a position adjacent to the flow control module 100 in the circulation line SGR; a second circulation valve SGR-VL2 provided at a position adjacent to the ejector 200 in the circulation line SGR; a first pressure gauge PS1 provided in a first section 22A between the first supply valve VL1 and the flow control module 100 in the gas supply line 22; and a circulation line pressure gauge SGR-PS provided between the first circulation valve SGR-VL1 and the second circulation valve SGR-VL2 in the circulation line SGR.

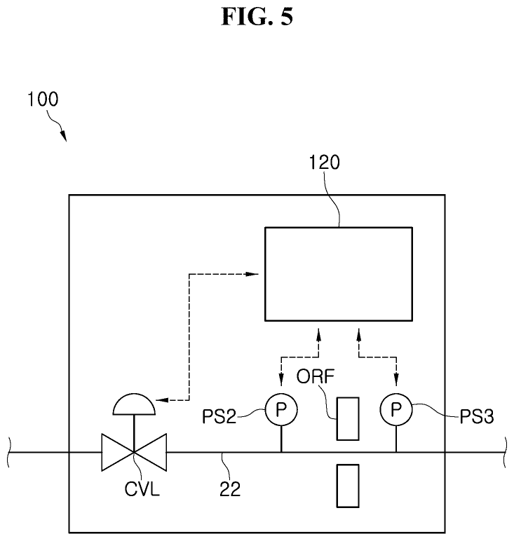

Referring to FIG. 5, the flow control module 100 includes: a control valve CVL provided at a position adjacent to the first supply valve VL1 and controlling the opening rate of the gas supply line 22; an orifice ORF provided at a position adjacent to the second supply valve VL2; a second pressure gauge PS2 provided in a second section 22B between the control valve CVL and the orifice ORF in the gas supply line 22; a third pressure gauge PS3 provided in a third section 22C between the orifice ORF and the second supply valve VL2; and a controller 120 that controls the control valve to maintain the pressure of the second section 22B in the gas supply line 22 at a set control pressure.

The first pressure gauge PS1 may measure the gas pressure in the first section 22A between the first supply valve VL1 and the control valve CVL, the second pressure gauge PS2 may measure the gas pressure in the second section 22B between the control valve CVL and the orifice ORF, and the third pressure gauge PS3 may measure the gas pressure in the third section 22C between the orifice ORF and the second supply valve VL2. The circulation line pressure gauge SGR-PS may measure the pressure between the first circulation valve SGR-VL1 and the second circulation valve SGR-VL2.

The gas supplying apparatus 20 may include: a dump line DMP branched from the circulation line SGR at a position between the first circulation valve SGR-VL1 and the second circulation valve SGR-VL2 and connected to a discharge end 30; and a dump valve DMP-VL provided on the dump line DMP. The dump line DMP is configured to discharge the gas remaining in the second section 22B of the gas supply line 22 to the outside. The dump valve DMP-VL may control whether the dump line DMP is open or not. The discharge end 30 is equipped with a pump for sucking gas, and when the dump valve DMP-VL is opened, a gas may be released through the discharge end 30 by vacuum pressure.

According to an embodiment of the present disclosure, openness between the gas supply line 22 and the circulation line SGR may be controlled based on the internal pressure of the gas supply line 22 and the control pressure of the flow control module 100.

Referring to FIG. 5, the flow control module 100 may include: the control valve CVL provided at a position adjacent to the first supply valve VL1 and regulating the opening area of a path through which a gas flows in the gas supply line 22; the orifice ORF provided adjacent to the second supply valve VL2; the second pressure gauge PS2 provided in a second section 22B between the control valve CVL and the orifice ORF in the gas supply line 22; and the third pressure gauge PS3 provided in a third section 22C between the orifice ORF and the second supply valve VL2. The flow control module 100 also includes the controller 120 electrically connected to the control valve CVL, the second pressure gauge PS2, and the third pressure gauge PS3. The controller 120 may be connected to a control device 50. According to an embodiment of the present disclosure, the circulation line SGR is connected in the second section 22B of the gas supply line 22, and a gas of the second section 22B may be discharged or introduced into the ejector 200 through the circulation line SGR.

The controller 120 receives recipe information about the supply flow rate of gas from the control device 50. The controller 120 may calculate the gas control pressure in the second section 22B from the recipe information. In addition, the controller 120 receives measured values of the second pressure gauge PS2 and the third pressure gauge PS3. The controller 120 may control the opening amount of the control valve CVL by comparing the pressure measurement values and the control pressure. The controller 120 may calculate the degree of opening of the control valve CVL, generate a control signal for the control valve CVL, and transmit the control signal to the control valve CVL. The control valve CVL may operate according to the received control signal.

The control valve CVL may be a piezo control valve. Inside the control valve CVL, a mechanism is configured to control the degree of opening of the gas supply line 22, and by driving the mechanism according to a control signal received from the controller 120, the opening area of the gas supply line 22 may be adjusted.

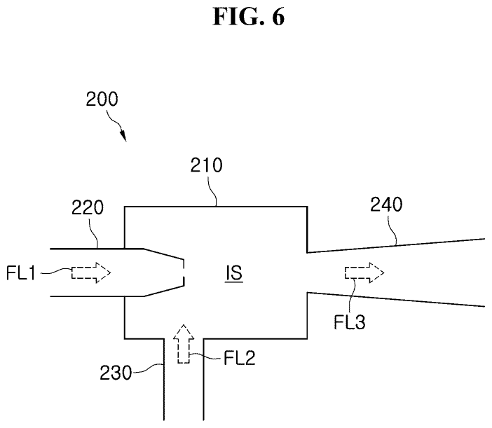

FIG. 6 shows the structure of an ejector 200 according to an embodiment of the present disclosure. The ejector 200 is a device that transfers fluid using the Venturi effect. The Venturi effect refers to the principle that fluid pressure decreases as the speed of a fluid increases pressure when the fluid passes through a narrow passage. Referring to FIG. 6, the ejector 200 includes: a body 210 forming an internal space IS; an inlet nozzle 220 that guides a high-pressure fluid FL1 into the internal space IS of the body 210; a suction nozzle 230 that guides a low-pressure fluid FL2 into the internal space IS of the body 210; and a diffuser nozzle 240 for discharging a fluid FL3 from the body 210. In the ejector 200, the high-pressure fluid FL1 flows in through the inlet nozzle 220, and at this time, the low-pressure fluid FL2 is sucked into the internal space of the body 210 due to the pressure of the high-pressure fluid FL1. The fluid FL3 in the internal space of the body 210 is discharged to the outside through the diffuser nozzle 240.

The ejector 200 includes: the body 210 forming the internal space IS; the inlet nozzle 220 formed to allow a gas provided from the gas source 40 to flow in; the suction nozzle 230 formed to allow a gas provided from the circulation line SGR to be sucked in; and the diffuser nozzle 240 for spraying a gas in the internal space IS into the gas supply line 22. According to an embodiment of the present disclosure, the inlet nozzle 220 is connected to the gas source 40 by means of a supply side valve VL0, the suction nozzle 230 is connected to the circulation line SGR, and the diffuser nozzle 240 is connected to the gas supply line 22. A gas supplied from the flow control module 100 to the circulation line SGR may be sucked back into the ejector 200 and provided again to the gas supply line 22.

According to an embodiment of the present disclosure, a gas remaining in the second section 22B during the first gas supply period may be discharged through the circulation line SGR. As the gas remaining in the second section 22B flows into the ejector 200 through the circulation line SGR, the gas may be reused. By discharging the remaining gas in the second section 22B through the circulation line SGR, hunting caused by the remaining pressure may be prevented.

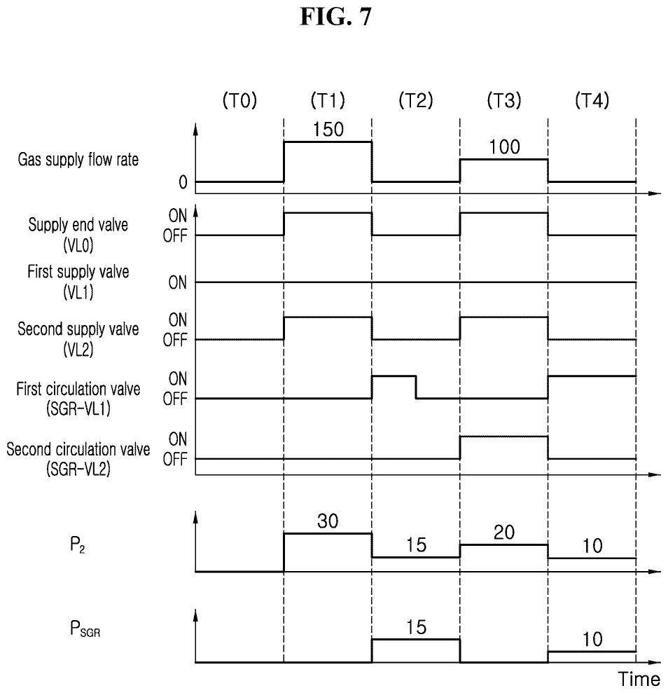

FIG. 7 is a timing diagram for gas flow rate control performed by a gas supplying apparatus 20 according to an embodiment of the present disclosure. The gas flow control according to the present disclosure may be performed by controlling each valve operation by commands from the control device 50.

According to the present disclosure, the second supply valve VL2 is set to repeatedly open and be closed by a pulse signal at a regular interval (e.g., 1 second), and gas may be supplied to the chamber 10 at a supply flow rate determined by means of the control valve CVL during the time the second supply valve VL2 is open. Referring to FIG. 7, gas is supplied in a pulse manner, and the flow rate of gas supplied is different for each pulse cycle.

It is set that at an initial timing TO, gas is not supplied, at a first timing T1, gas at a first flow rate (e.g., 150 cc/min) is supplied to the chamber 10, at a second timing T2, supply of gas is blocked, at a third timing T3, gas at a first flow rate (e.g., 100 cc/min) is supplied to the chamber 10, and at a fourth timing T4, supply of gas is blocked.

Referring to FIG. 7, whether to supply or block gas is determined by controlling the opening and closing of the supply side valve VL0 and the second supply valve VL2 with the first supply valve VL1 open. In addition, the supply and blocking of gas may be controlled by opening and closing the first supply valve VL1 together with the second supply valve VL2. Alternatively, whether gas is supplied or blocked may be controlled by independently opening and closing the first supply valve VL1.

At the first timing T1 when the second supply valve VL2 is opened, the control valve CVL is controlled so that a first control pressure (e.g., 30 Torr) corresponding to the first gas supply flow rate (e.g., 150 cc/min) is maintained in the second section 22B. At the first timing T1, the second supply valve VL2 is opened to supply gas, and the first control pressure (e.g., 30 Torr) corresponding to the first gas supply flow rate (e.g., 150 cc/min) may be maintained in the second section 22B by control of the control valve CVL. In this case, gas at the first supply flow rate (e.g., 150 cc/min) is supplied to the chamber 10.

At the second timing T2 when the second supply valve VL2 is closed, if a pressure P₂ of a gas remaining in the second section 22B is greater than a second control pressure (e.g., 20 Torr) corresponding to the second gas supply flow rate (e.g., 100 cc/min) to be supplied at the third timing T3, a first circulation valve SGR-VL1 is controlled to open for a set period of time (e.g., 0.5 seconds). At the third timing T3, the supply of gas is blocked by the second supply valve VL2, and at this time, the remaining pressure (30 Torr) in the second section 22B is greater than the second control pressure (e.g., 20 Torr) for the next gas supply. In this case, the pressure P₂ remaining on the upstream side of the orifice ORF may be reduced by opening the first circulation valve SGR-VL1. That is, the first circulation valve SGR-VL1 may be set to open when the pressure of the gas remaining in the second section 22B is greater than the control pressure for supplying the next gas. As the first circulation valve SGR-VL1 is opened, part of the gas remaining in the second section 22B is discharged into the circulation line SGR, and a low-pressure (e.g., 15 Torr) gas remains in the second section 22B and the circulation line SGR.

If the difference between the pressure P₂ of the gas remaining in the second section 22B and the pressure P_{SGR} of the gas remaining in the circulation line SGR is greater than a reference value (e.g., 10 Torr), the second circulation valve SGR-VL2 is controlled to open at the third timing T3 when the second supply valve VL2 is opened. The pressure P₂ of the gas remaining in the second section 22B is set to be greater than or equal to the pressure P_{SGR} of the gas remaining in the circulation line SGR. At the third timing T3, the gas is supplied back to the chamber 10 by means of the second supply valve VL2, and the second control pressure (e.g., 20 Torr) corresponding to the second flow rate (e.g., 100 cc/min) is maintained in the second section 22B by the control valve CVL. At this time, by opening the second circulation valve SGR-VL2, the gas remaining in the circulation line SGR may be sucked into the ejector 200. Gas at the second supply flow rate (e.g. 100 cc/min) is supplied to chamber 10.

Whether to open the second circulation valve SGR-VL2 is determined depending on whether the difference between the pressure P₂ of the second section 22B and the pressure P_{SGR} of the circulation line SGR is smaller than the reference value. The pressure P₂ of the second section 22B is preferably maintained to be greater than the pressure P_{SGR} of the circulation line SGR. Thus, when a gas flows into the circulation line SGR by opening the first circulation line SGR-VL1, the second circulation valve SGR-VL2 may be opened to maintain a difference above a predetermined reference value. That is, when the difference between the pressure P₂ of the second section 22B and the pressure P_{SGR} of the circulation line SGR is smaller than the reference value, the second circulation valve SGR-VL2 may be set to open. The gas remaining in the circulation line SGR is supplied back to the gas supply line 22 through the ejector 200, and the gas pressure in the circulation line SGR may be maintained in a very low state (close to 0).

Thereafter, at the fourth timing T4, the supply of gas is blocked by the second supply valve VL2, and when necessary, the first circulation valve SGR-VL1 is opened to remove the pressure remaining in the second section 22B. In this case, by opening the second circulation valve SGR-VL2 at the next timing, the difference between the pressure P₂ of the second section 22B and the pressure P_{SGR} of the circulation line SGR may be made greater than the reference value.

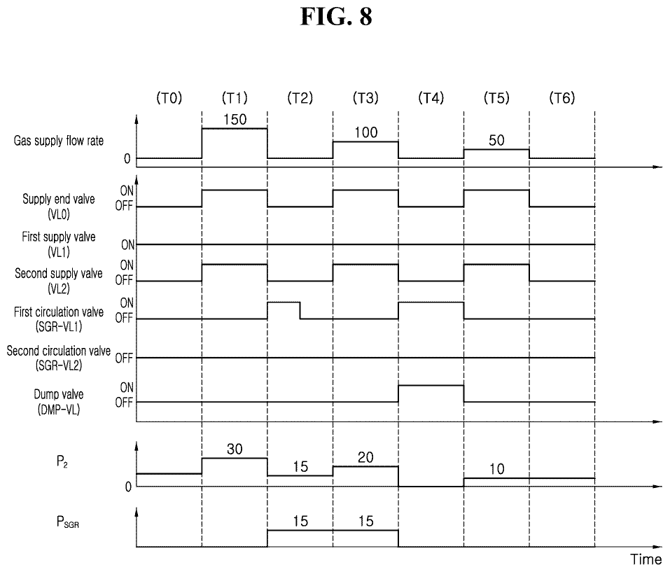

FIG. 8 is a timing diagram for gas flow rate control performed by a gas supplying apparatus 20 to which a dump line DMP is applied according to an embodiment of the present disclosure. Compared to FIG. 7, FIG. 8 further includes a process of discharging a gas remaining in the second section 22B through the dump line DMP.

During the blocking time when the second supply valve VL2 is closed, based on the internal pressures P₁, P₂, and P₃ of the gas supply line 22, the internal pressure P_{SGR} of the circulation line SGR, and the control pressure for gas supply after the blocking time, the opening of the dump valve DMP-VL is controlled.

The operation from the initial timing T0 to the third timing T3 is the same as the control method described in FIG. 7. At the third timing T3, gas of the second control pressure (e.g., 20 Torr) remains in the second section 22B, and gas introduced into the circulation line SGR at the second timing T2 remains. The opening of the dump valve DMP-VL is controlled based on the internal pressures P₁, P₂, and P₃ of the gas supply line 22, the internal pressure P_{SGR} of the circulation line SGR, and the control pressure for gas supply after the blocking time.

At the first timing T1 when the second supply valve VL2 is opened, the control valve CVL is controlled so that the first control pressure (e.g., 30 Torr) corresponding to the first gas supply flow rate (e.g., 150 cc/min) is maintained in the second section 22B. In this case, gas at the first supply rate (e.g., 150 cc/min) is supplied to the chamber 10.

At the second timing T2 when the second supply valve VL2 is closed, if the pressure P₂ of a gas remaining in the second section 22B is greater than the second control pressure (e.g., 20 Torr) corresponding to the second gas supply flow rate (e.g., 100 cc/min) in the third timing T3, the second circulation valve SGR-VL2 is controlled to open for a set period of time (e.g., 0.5 seconds).

At the third timing T3 when the second supply valve VL2 is opened, the control valve CVL is controlled so that the second control pressure (e.g., 20 Torr) is maintained in the second section 22B. In this case, gas at the second supply rate (e.g., 100 cc/min) is supplied to the chamber 10.

At the fourth timing T4 when the second supply valve VL2 is closed, if (i) the pressure PI of the first section 22A is greater than the first reference value (e.g., 100 Torr), (ii) the pressure P_{SGR} in the circulation line SGR is greater than the second reference value (e.g. 10 Torr), and (iii) the pressure P₂ of the second section 22B is greater than a third control pressure (e.g., 10 Torr) corresponding to a third gas supply flow rate (e.g., 50 cc/min) to be supplied at a fifth timing T5, the dump valve DMP-VL is controlled to open. The gas remaining in the second section 22B of the gas supply line and the circulation line SGR may be discharged to the discharge end 30 through the dump line DMP.

At the fifth timing T5 when the second supply valve VL2 is opened, the control valve CVL is controlled so that the third control pressure (e.g., 10 Torr) is maintained in the second section 22B. In this case, gas at the third supply rate (e.g., 50 cc/min) is supplied to the chamber 10.

On the other hand, if (i) the pressure P₁ of the first section 22A is below the first reference value (e.g., 100 Torr), (ii) the pressure P_{SGR} in the circulation line SGR is below the reference value (e.g. 10 Torr), or (iii) the pressure P₂ of the gas remaining the second section 22B is lower than the control pressure for the next gas supply (e.g., 10 Torr), the dump valve DMP-VL may be controlled to be closed.

When the pressure P₂ on the upstream side (i.e., second section 22B) of the orifice ORF is greater than the control pressure for the next gas supply and the gas pressure in the circulation line SGR) is above the reference value, it is no longer difficult to direct gas into the circulation line SGR. In this case, hunting of the gas flow rate may be prevented by discharging gas in advance through the dump line DMP.

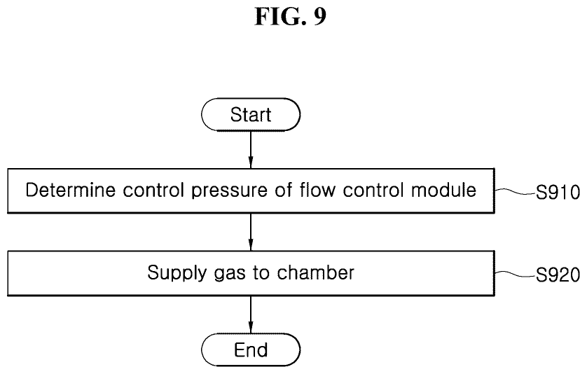

FIG. 9 is a flowchart showing a gas supply control method S900 performed by a gas supplying apparatus 20 according to an embodiment of the present disclosure. The gas supply control method S900 includes: determining (S910) the control pressure of a flow control module 100 based on the supply flow rate of gas; and supplying (S920) gas to a chamber 10 at a supply flow rate corresponding to the control pressure.

A second supply valve VL2 is set to repeatedly open and be closed by a pulse signal at a regular interval (e.g., 1 second), and gas is supplied to the chamber 10 at a supply flow rate determined by means of a control valve CVL during the time the second supply valve VL2 is open. For example, in step S910, the second supply valve VL2 is closed to block the supply of gas, and in step S920, the second supply valve VL2 is opened and gas may be supplied to the chamber 10 at a set flow rate. Steps S910 and S920 may be performed repeatedly. The operation of step S910 may be performed at the initial timing TO, the second timing T2, and the fourth timing T4 in FIGS. 7 and 8, while the operation of step S920 may be performed at the first timing T1, the third timing T3, and the fifth timing T5 in FIGS. 7 and 8.

At the initial timing TO, the second supply valve VL2 is closed and gas is not supplied to the chamber 10. At this time, as in step S910, a first control pressure (e.g., 30 Torr) corresponding to a first supply flow rate (e.g., 150 cc/min) in the first timing T1 is determined.

At the first timing T1 when the second supply valve VL2 is opened, the control valve is controlled so that the first control pressure (e.g., 30 Torr) corresponding to the first gas supply flow rate (e.g., 150 cc/min) is maintained in a second section 22B. At this time, as in step S920, a process of supplying gas to the chamber 10 is performed at a supply flow rate (e.g., 150 cc/min) corresponding to the first control pressure (e.g., 30 Torr).

At the second timing T2 when the second supply valve VL2 is closed, if the pressure of a gas remaining in the second section 22B is greater than a second control pressure (e.g., 20 Torr) corresponding to a second gas supply flow rate (e.g., 100 cc/min) in the third timing T3, a second circulation valve SGR-VL2 is controlled to open for a set period of time (e.g., 0.5 seconds). At this time, as in step S910, a process of determining the second control pressure (e.g., 20 Torr) corresponding to the second supply flow rate (e.g., 100 cc/min) of gas to be supplied at the third timing T3 is performed.

At the third timing T3 when the second supply valve VL2 is opened, as in step S920, a process of supplying gas to the chamber 10 is performed at a supply flow rate (e.g., 100 cc/min) corresponding to the second control pressure (e.g., 20 Torr). If the difference between a pressure P₂ of the gas remaining in the second section 22B and a pressure P_{SGR} of a gas remaining in a circulation line SGR is greater than a reference value (e.g., 10 Torr), the second circulation valve SGR-VL2 is controlled to open. At the third timing T3, the gas is supplied back to the chamber 10 by means of the second supply valve VL2, and the second control pressure (e.g., 20 Torr) corresponding to the second flow rate (e.g., 100 cc/min) is maintained in the second section 22B by means of the control valve CVL. At this time, by opening the second circulation valve SGR-VL2, the gas remaining in the circulation line SGR may be sucked into an ejector 200. Gas at the second supply flow rate (e.g. 100 cc/min) is supplied to chamber 10.

At the fourth timing T4 when the second supply valve VL2 is closed, as in step S910, a process of determining a third control pressure (e.g., 10 Torr) corresponding to a third supply flow rate (e.g., 50 cc/min) of gas to be supplied at the fifth timing T5 is performed. At the fourth timing T4 when the second supply valve VL2 is closed, if (i) a pressure P₁ of a first section 22A is greater than a first reference value (e.g., 100 Torr), (ii) the pressure P_{SGR} in the circulation line SGR is greater than a second reference value (e.g. 10 Torr), and (iii) the pressure P₂ of the second section 22B is greater than a third control pressure (e.g., 10 Torr) corresponding to a third gas supply flow rate (e.g., 50 cc/min) to be supplied at the fifth timing T5, a dump valve DMP-VL is controlled to open. The gas remaining in the second section 22B of the gas supply line and the circulation line SGR may be discharged to a discharge end 30 through a dump line DMP.

At the fifth timing T5 when the second supply valve VL2 is opened, the control valve CVL is controlled such that the third control pressure (e.g. 10 Torr) is maintained in the second section 22B. As in step S902, a process of supplying gas to the chamber 10 is performed at a supply flow rate (e.g., 50 cc/min) corresponding to the third control pressure (e.g., 10 Torr).

The gas supply control method described above may be controlled by the control device 50 of the substrate processing apparatus 1.

According to the present disclosure, the control device 50 transmits information about the supply flow rate of gas to the controller 120 of the flow control module 100. The controller 120 determines the control pressure of the flow control module 100 based on the supply flow rate of gas. The controller 120 controls the control valve CVL to maintain the control pressure in the second section 22B while gas is supplied to the chamber 10. The control device 50 may control whether to open the first circulation valve SGR-VL based on the pressure P₂ of the gas remaining in the second section 22B and the control pressure of the flow control module 100. The control device 50 may control the gas supplying apparatus 20 so that the gas supply control process as described with reference to FIG. 7 or 8 is performed.

The present embodiments and the drawings accompanying this specification only clearly show some of the technical ideas included in the present disclosure, and it will be apparent that all modifications and specific embodiments that may be easily inferred by those skilled in the art within the scope of the technical idea included in the specification and drawings of the present disclosure are included in the scope of the present disclosure.

Therefore, the spirit of the present disclosure should not be limited to the described embodiments, and it will be said that not only the claims to be described later but also all things that are equivalent to the claims or have equivalent modifications belong to the scope of the present disclosure.

What is claimed is:

1. A gas supplying apparatus that supplies a gas to a chamber adapted to perform processing on a substrate, the gas supplying apparatus comprising:
a gas supply line connected from a gas source to the chamber and providing a flow path for the gas;
a circulation line branching off from a branch point of the gas supply line and connected to an upstream side of the branch point;
an ejector having an internal space that sucks a gas provided from the circulation line using a pressure of the gas introduced from the gas source, and injecting the gas in the internal space into the gas supply line; and
a flow control module configured to regulate a flow rate of the gas supplied to the chamber by controlling the pressure of the gas in the gas supply line,
wherein openness between the gas supply line and the circulation line is controlled based on an internal pressure of the gas supply line and a control pressure of the flow control module.

2. The gas supplying apparatus of claim 1, wherein the ejector comprises:
a body forming the internal space;
an inlet nozzle provided to allow the gas provided from the gas source to flow in;
a suction nozzle provided to allow the gas provided from the circulation line to be sucked in; and
a diffuser nozzle for spraying the gas in the internal space into the gas supply line.

3. The gas supplying apparatus of claim 1, further comprising:
a first supply valve provided between the ejector and the flow control module;
a second supply valve provided between the flow control module and the chamber;
a first circulation valve provided at a position adjacent to the flow control module in the circulation line;
a second circulation valve provided at a position adjacent to the ejector in the circulation line;
a first pressure gauge provided in a first section between the first supply valve and the flow control module in the gas supply line; and
a circulation line pressure gauge provided between the first circulation valve and the second circulation valve in the circulation line.

4. The gas supplying apparatus of claim 3, wherein the flow control module comprises:
a control valve provided at a position adjacent to the first supply valve and controlling an opening rate of the gas supply line;
an orifice provided at a position adjacent to the second supply valve;
a second pressure gauge provided in a second section between the control valve and the orifice in the gas supply line;
a third pressure gauge provided in a third section between the orifice and the second supply valve; and
a controller configured to control the control valve to maintain a pressure of the second section in the gas supply line at a set control pressure.

5. The gas supplying apparatus of claim 4, wherein the second supply valve is set to repeatedly open and be closed by a pulse signal at regular intervals, and the gas is supplied to the chamber at a supply flow rate determined by means of the control valve during a time the second supply valve is open.

6. The gas supplying apparatus of claim 4, wherein at a first timing when the second supply valve is opened, the control valve is controlled so that a first control pressure corresponding to a first gas supply flow rate is maintained in the second section, and
at a second timing when the second supply valve is closed, if a pressure of the gas remaining in the second section is greater than a second control pressure corresponding to a second gas supply flow rate in a third timing, the first circulation valve is controlled to open for a set period of time.

7. The gas supplying apparatus of claim 5, wherein if a difference between a pressure of the gas remaining in the second section and a pressure of the gas remaining in the circulation line is greater than a reference value, the second circulation valve is controlled to open at a third timing when the second supply valve is opened.

8. The gas supplying apparatus of claim 4, further comprising:
a dump line branched from the circulation line at a position between the first circulation valve and the second circulation valve, and connected to a discharge end; and
a dump valve provided on the dump line.

9. The gas supplying apparatus of claim 8, wherein during a blocking time when the second supply valve is closed, an opening of the dump valve is controlled based on internal pressures of the gas supply line, an internal pressure of the circulation line, and a control pressure for gas supply after the blocking time.

10. The gas supplying apparatus of claim 9, wherein at a first timing when the second supply valve is opened, the control valve is controlled so that a first control pressure corresponding to a first gas supply flow rate is maintained in the second section,
at a second timing when the second supply valve is closed, if a pressure of the gas remaining in the second section is greater than a second control pressure corresponding to a second gas supply flow rate in a third timing, the second circulation valve is controlled to open for a set period of time,
at a third timing when the second supply valve is opened, the control valve is controlled so that the second control pressure is maintained in the second section, and
at a fourth timing when the second supply valve is closed, if a pressure of the first section is greater than a first reference value, a pressure of the circulation line is greater than a second reference value, and a pressure of the second section is greater than a third control pressure corresponding to a third gas supply flow rate in a fifth timing, the dump valve is controlled to open.

11. A gas supply control method performed by a gas supplying apparatus comprising: a gas supply line connected from a gas source to a chamber and providing a flow path for a gas; a circulation line branching off from a branch point of the gas supply line and connected to an upstream side of the branch point; an ejector having an internal space that sucks a gas provided from the circulation line using a pressure of the gas introduced from the gas source, and injecting the gas in the internal space into the gas supply line; and a flow control module configured to regulate a flow rate of the gas supplied to the chamber by controlling the pressure of the gas in the gas supply line, the method comprising:
determining a control pressure of the flow control module based on a supply flow rate of the gas; and
supplying the gas to the chamber at a supply flow rate corresponding to the control pressure,
wherein openness between the gas supply line and the circulation line is controlled based on an internal pressure of the gas supply line and a control pressure of the flow control module.

12. The method of claim 11, wherein the gas supplying apparatus comprises:
a first supply valve provided between the ejector and the flow control module;
a second supply valve provided between the flow control module and the chamber;
a first circulation valve provided at a position adjacent to the flow control module in the circulation line;
a second circulation valve provided at a position adjacent to the ejector in the circulation line;
a first pressure gauge provided in a first section between the first supply valve and the flow control module in the gas supply line; and
a circulation line pressure gauge provided between the first circulation valve and the second circulation valve in the circulation line.

13. The method of claim 12, wherein the flow control module comprises:
a control valve provided at a position adjacent to the first supply valve and controlling an opening rate of the gas supply line;
an orifice provided at a position adjacent to the second supply valve;
a second pressure gauge provided in a second section between the control valve and the orifice in the gas supply line;
a third pressure gauge provided in a third section between the orifice and the second supply valve; and
a controller configured to control the control valve to maintain a pressure of the second section in the gas supply line at a set control pressure.

14. The method of claim 13, wherein the second supply valve is set to repeatedly open and be closed by a pulse signal at regular intervals, and the gas is supplied to the chamber at a supply flow rate determined by means of the control valve during a time the second supply valve is open.

15. The method of claim 13, wherein at a first timing when the second supply valve is opened, the control valve is controlled so that a first control pressure corresponding to a first gas supply flow rate is maintained in the second section, and
at a second timing when the second supply valve is closed, if a pressure of a gas remaining in the second section is greater than a second control pressure corresponding to a second gas supply flow rate in a third timing, the second circulation valve is controlled to open for a set period of time.

16. The method of claim 15, wherein if a difference between the pressure of the gas remaining in the second section and a pressure of the gas remaining in the circulation line is greater than a reference value, the second circulation valve is controlled to open at a third timing when the second supply valve is opened.

17. The method of claim 13, further comprising:
a dump line branched from the circulation line at a position between the first circulation valve and the second circulation valve, and connected to a discharge end; and
a dump valve provided on the dump line.

18. The method of claim 17, wherein during a blocking time when the second supply valve is closed, an opening of the dump valve is controlled based on internal pressures of the gas supply line, an internal pressure of the circulation line, and a control pressure for gas supply after the blocking time.

19. The method of claim 18, wherein at a first timing when the second supply valve is opened, the control valve is controlled so that a first control pressure corresponding to a first gas supply flow rate is maintained in the second section,
at a second timing when the second supply valve is closed, if a pressure of the gas remaining in the second section is greater than a second control pressure corresponding to a second gas supply flow rate in a third timing, the second circulation valve is controlled to open for a set period of time,
at a third timing when the second supply valve is opened, the control valve is controlled so that the second control pressure is maintained in the second section, and
at a fourth timing when the second supply valve is closed, if a pressure of the first section is greater than a first reference value, a pressure of the circulation line is greater than a second reference value, and a pressure of the second section is greater than a third control pressure corresponding to a third gas supply flow rate in a fifth timing, the dump valve is controlled to open.

20. A substrate processing apparatus comprising:
a chamber in which processing on a substrate is performed;
a gas supplying apparatus configured to supply a gas to the chamber; and
a control device configured to control an operation of the gas supplying apparatus,
wherein the gas supplying apparatus comprises:
a gas supply line connected from a gas source to a chamber and providing a flow path for a gas;
a circulation line branching off from a branch point of the gas supply line and connected to an upstream side of the branch point;
an ejector having an internal space that sucks a gas provided from the circulation line using a pressure of the gas introduced from the gas source, and injecting the gas in the internal space into the gas supply line;
a flow control module configured to regulate a flow rate of the gas supplied to the chamber by controlling the pressure of the gas in the gas supply line;
a first supply valve provided between the ejector and the flow control module;
a second supply valve provided between the flow control module and the chamber;
a first circulation valve provided at a position adjacent to the flow control module in the circulation line connecting the ejector and the flow control module;
a second circulation valve provided at a position adjacent to the ejector in the circulation line;
a dump line branched from the circulation line at a position between the first circulation valve and the second circulation valve, and connected to a discharge end;
a dump valve provided on the dump line;
a first pressure gauge provided in a first section between the first supply valve and the flow control module in the gas supply line; and
a circulation line pressure gauge provided between the first circulation valve and the second circulation valve in the circulation line,
wherein the flow control module comprises:
a control valve provided at a position adjacent to the first supply valve and controlling an opening rate of the gas supply line;
an orifice provided at a position adjacent to the second supply valve;
a second pressure gauge provided in a second section between the control valve and the orifice in the gas supply line;
a third pressure gauge provided in a third section between the orifice and the second supply valve; and
a controller configured to control the control valve to maintain a pressure of the second section in the gas supply line at a set control pressure,
wherein the control device transmits information about a supply flow rate of the gas to the controller of the flow control module,
the controller determines a control pressure of the flow control module based on the supply flow rate of the gas, and controls the control valve to maintain the control pressure in the second section while the gas is supplied to the chamber, and
the control device controls whether to open the first circulation valve based on a pressure of the gas remaining in the second section and a control pressure of the flow control module.
